(19) United States
(12) Patent Application Publication
(10) Pub. No.: US 2025/0030220 A1
(43) Pub. Date: Jan. 23, 2025

(54) SEMICONDUCTOR LASER ELEMENT

(71) Applicant: SONY SEMICONDUCTOR SOLUTIONS CORPORATION, KANAGAWA (JP)

(72) Inventors: YUTA ISOZAKI, KUMAMOTO (JP); YUICHIRO KIKUCHI, KUMAMOTO (JP); MAKOTO OOTA, KUMAMOTO (JP); SHINSUKE NOZAWA, KUMAMOTO (JP); HIDEKAZU KAWANISHI, TOKYO (JP)

(21) Appl. No.: 18/574,994

(22) PCT Filed: Mar. 23, 2022
(86) PCT No.: PCT/JP2022/013335

§ 371 Date: Dec. 28, 2023

(30) Foreign Application Priority Data
Jul. 8, 2021 (JP) 2021-113820

(51) Int. Cl. H01S 5/042; H01S 5/02; H01S 5/22

(52) U.S. Cl. CPC H01S 5/04256; H01S 5/0206; H01S 5/22

(57) ABSTRACT

Provided is a semiconductor laser element in which a step or edge crack is suppressed from being generated in an ITO layer or a semiconductor portion in contact with the ITO layer on a front end surface or a rear end surface during cleavage of a wafer in a ridge waveguide type end surface emission laser to improve reliability and yield. The configuration includes a GaN substrate, a nitride semiconductor layer of a first conductivity type laminated on the GaN substrate, an active layer laminated on the nitride semiconductor layer of the first conductivity type, a nitride semiconductor layer of a second conductivity type laminated on the active layer and formed in a ridge waveguide structure, transparent conductive film side bands laminated on the nitride semiconductor layer of the second conductivity type and extending in a band shape along a longitudinal direction toward both end surfaces, a transparent conductive film provided continuously with the transparent conductive film side bands, laminated on the nitride semiconductor layer of the second conductivity type, and formed with each of regions sandwiched between the transparent conductive film side bands and cut in a rectangular shape to be in contact with the end surfaces, an insulating layer laminated on the transparent conductive film, and a metal layer laminated on the insulating layer.

### TECHNICAL FIELD

The present disclosure relates to a semiconductor laser element, and more particularly to a semiconductor laser element having a ridge.

### BACKGROUND ART

In a compound semiconductor laser element, a stripe laser is mainly used, which is capable of increasing a threshold current density by providing a current confinement layer to narrow a current path of an active layer and thus lowering the threshold current itself. The stripe laser forms a ridge (meaning channel or edge) on an upper surface of a p-side semiconductor layer above the active layer. Then, an anode electrode is formed on the ridge to establish electrical connection.

In a gallium nitride (GaN)-based ridge waveguide laser, a transparent conductive film includes indium tin oxide (ITO: Indium Tin Oxide (hereinafter referred to as “ITO”)) is generally used for the anode electrode. ITO is a conductive and transparent substance. That is, it is a substance that allows light and electricity to pass well. ITO is suitable as an anode electrode of a semiconductor laser element because transmittance in a visible light region is high and thus there is no optical loss of laser light and an electrical conductor is good.

Furthermore, the ridge formed on a top of the GaN-based ridge waveguide laser is generally formed by performing reactive ion etching (RIE: Reactive Ion Etching (hereinafter referred to as “RIE”)) on the laminated layers of ITO and p-type GaN.

Therefore, both side surfaces of the ridge formed by RIE are substantially perpendicular, and stress concentration is likely to occur at a root portion of the ridge when wafer of the semiconductor laser element is cleaved.

Due to such stress concentration, a stripe-shaped step may be generated on a front end surface which is a light emission end surface and a rear end surface which is a light reflection end surface configuring an end surface of the ridge at the time of cleavage, or a crack may be generated on an edge of a semiconductor portion. In addition, such a step or a crack adversely affects reliability, and the ITO layer is disposed in the vicinity of the active layer, so that the characteristics of the laser may be deteriorated.

Patent Document 1 discloses a prior art for suppressing an adverse effect on reliability and deterioration of laser characteristics caused by the step generated at the time of such cleavage.

Specifically, there is disclosed a semiconductor light-emitting element including a semiconductor substrate, a lower cladding layer formed on the semiconductor substrate and having a first conductivity type, an active layer formed on the lower cladding layer, a cap layer formed on the active layer and having a second conductivity type opposite to the first conductivity type, a current confinement structure formed on the cap layer, an upper electrode layer formed on the current confinement structure, and a lower electrode layer electrically connected to the lower cladding layer. Then, the semiconductor light-emitting element includes a step confinement layer interposed between the active layer and the current confinement structure. That is, the step confinement layer is interposed between the active layer and the current confinement structure to confine the influence of the step.

Furthermore, Patent Document 2 discloses a prior art related to a stripe laser having a highly reliable ridge in which light absorption by an electrode is suppressed.

Specifically, there is disclosed a semiconductor laser element including an electrode formed on the ridge, in which the electrode covers an upper surface of the ridge and has a flat portion and inclined portions disposed on both sides of the flat portion with respect to the upper surface of the ridge, regions extending from side surfaces of the ridge to the inclined portions of the electrode are covered with a protective film, and a tip portion of the protective film is formed at a position higher than the upper surface of the electrode and covers a part of the flat portion.

Furthermore, Patent Document 3 discloses a prior art related to a semiconductor laser diode that improves reliability and efficiency by controlling a current injection amount using ITO.

Specifically, in a first cladding layer of a ridge, ITO, which is a material having transparency and enabling entry of a laser mode, and a material having light absorbency are alternately juxtaposed along the direction of an optical resonator. The semiconductor laser diode is configured to be able to control the current injection amount so as not to locally apply a current to a surface region, that is, so as not to generate a so-called “hot spot” with the juxtaposition in this way.

### CITATION LIST

### Patent Document

Patent Document 1: Japanese Patent Application Laid-Open No. 2010-093128
Patent Document 2: Japanese Patent Application Laid-Open No. 2015-167263
Patent Document 3: Japanese Translation of PCT International Application No. 2020-524407

### SUMMARY OF THE INVENTION

### Problems to be Solved by the Invention

However, the technique disclosed in Patent Document 1 confines the influence of the step, and does not prevent the step or the crack from being generated.

The technique disclosed in Patent Document 2 solves a problem that a material includes a nitride semiconductor such as GaN has a higher contact resistance than GaAs and may increase an operating voltage of a laser. The electrode has the flat portion and inclined portions disposed on both sides of the flat portion with respect to the upper surface of the ridge, and is configured to cover the regions from the side surfaces of the ridge to the inclined portions of the electrode with the protective film. Therefore, a step or a crack is not intended to be prevented from being generated.

The technique disclosed in Patent Document 3 is a technique using ITO, but allows the amount of current injection to be controlled so as not to generate a so-called “hot spot” so as not to locally apply a current to the surface region, and is not intended to prevent generation of a step or a crack. Furthermore, the use and shape of ITO to be used are also different.

The present disclosure has been made in view of such problems, and is intended to provide a semiconductor laser element with improved reliability by suppressing the generation of a step in an ITO layer or a semiconductor portion in contact with the ITO layer at the time of cleavage of a wafer, and the generation of a crack in an edge of a semiconductor portion on a front end surface or a rear end surface. Note that, hereinafter, the “front end surface” and the “rear end surface” may be collectively referred to as “both end surfaces”.

### Solutions to Problems

The present disclosure has been made to solve the above-described problems, and a first aspect thereof is a semiconductor laser element including: a GaN substrate; a nitride semiconductor layer of a first conductivity type laminated on the GaN substrate; an active layer laminated on the nitride semiconductor layer of the first conductivity type; a nitride semiconductor layer of a second conductivity type laminated on the active layer and formed in a ridge waveguide structure; transparent conductive film side bands laminated on the nitride semiconductor layer of the second conductivity type and extending in a band shape along a longitudinal direction toward both end surfaces; a transparent conductive film provided continuously with the transparent conductive film side bands, laminated on the nitride semiconductor layer of the second conductivity type, and formed with each of regions sandwiched between the transparent conductive film side bands and cut in a rectangular shape to be in contact with the end surfaces; an insulating layer laminated on the transparent conductive film; and a metal layer laminated on the insulating layer.

Furthermore, in the first aspect, the nitride semiconductor layer of the first conductivity type may include a cladding layer and a guide layer.

Furthermore, in the first aspect, the nitride semiconductor layer of the second conductivity type may include a cladding layer and a guide layer.

Furthermore, In the first aspect, the metal layer may include a pad metal layer, a barrier metal layer, and a bonding metal layer.

Furthermore, in the first aspect, the metal layer laminated on a cleavage line to be the front end surface and the rear end surface may be a barrier metal layer.

Furthermore, in the first aspect, the transparent conductive film may include indium tin oxide (ITO), indium titanium oxide (ITiO), aluminum oxide-doped zinc oxide (AZO), or IGZO (InGaZnOx).

Furthermore, in the first aspect, the regions of the transparent conductive film sandwiched between the transparent conductive film side bands and cut into the rectangular shape may be covered with an insulating layer.

Furthermore, in the first aspect, the transparent conductive film formed in a pattern, a character, a symbol, or a combination thereof may be disposed in the region of the transparent conductive film sandwiched between the transparent conductive film side bands and cut into the rectangular shape.

Furthermore, in the first aspect, the pattern, the character, the symbol, or the combination thereof of the transparent conductive film formed in the regions of the transparent conductive film sandwiched between the transparent conductive film side bands and cut into the rectangular shape may be different between the front end surface and the rear end surface.

According to the above aspect, there can be provided a semiconductor laser element with improved reliability and yield by suppressing the generation of a step in an ITO layer or a semiconductor portion in contact with the ITO layer at the time of cleavage of a wafer, and the generation of a crack in an edge of a semiconductor portion on a front end surface or a rear end surface.

### BRIEF DESCRIPTION OF DRAWINGS

FIG. 1 is an external perspective view of a semiconductor laser element according to the present disclosure.

FIG. 2 is a plan view of the semiconductor laser element according to the present disclosure.

FIG. 3 is a cross-sectional view of the semiconductor laser element according to the present disclosure as viewed in a direction of A-A.

FIG. 4 is a cross-sectional view of the semiconductor laser element according to the present disclosure as viewed in a direction of B-B.

FIG. 5 is a cross-sectional view of a front end surface portion of the semiconductor laser element according to the present disclosure as viewed in a direction of C-C.

FIG. 6 is an illustrative view of a method for manufacturing the semiconductor laser element according to the present disclosure (part 1).

FIG. 7 is an illustrative view of the method for manufacturing the semiconductor laser element according to the present disclosure (part 2).

FIG. 8 is an illustrative view of the method for manufacturing the semiconductor laser element according to the present disclosure (part 3).

FIG. 9 is an illustrative view of the method for manufacturing the semiconductor laser element according to the present disclosure (part 4).

FIG. 10 is an illustrative view of the method for manufacturing the semiconductor laser element according to the present disclosure (part 5).

FIG. 11 is an illustrative view of the method for manufacturing the semiconductor laser element according to the present disclosure (part 6).

FIG. 12 is an illustrative view of the method for manufacturing the semiconductor laser element according to the present disclosure (part 7).

FIG. 13 is an illustrative view of the method for manufacturing the semiconductor laser element according to the present disclosure (part 8).

FIG. 14 is an illustrative view of the method for manufacturing the semiconductor laser element according to the present disclosure (part 9).

FIG. 15 is an illustrative view of the method for manufacturing the semiconductor laser element according to the present disclosure (part 10).

FIG. 16 is an illustrative view of the method for manufacturing the semiconductor laser element according to the present disclosure (part 11).

FIG. 17 is a plan view of a first configuration example of a semiconductor laser element according to a second embodiment of the present disclosure.

FIG. 18 is a plan view of a second configuration example of a semiconductor laser element according to the second embodiment of the present disclosure.

FIG. 19 is a plan view of a third configuration example of a semiconductor laser element according to the second embodiment of the present disclosure.

FIG. 20 is a schematic diagram illustrating a step generated in the semiconductor laser element.

FIG. 21 is a schematic diagram illustrating a crack generated in the semiconductor laser element.

FIG. 22 is a schematic plan view of a semiconductor laser element in which measures against a step and a crack are taken.

### MODE FOR CARRYING OUT THE INVENTION

Next, a mode for carrying out the present disclosure (hereinafter, referred to as a “embodiment”) will be described in the following order with reference to the drawings. Note that, in the following drawings, the same or similar parts are denoted by the same or similar reference numerals. However, the drawings are schematic, and dimensional ratios and the like of each part do not necessarily match actual ones. Furthermore, it is needless to say that dimensional relationships and ratios are partly different between the drawings.
1. Problem of a semiconductor laser element
2. Semiconductor laser element according to a first embodiment of the present disclosure
3. Method for manufacturing a semiconductor laser element according to the first embodiment of the present disclosure
4. Semiconductor laser element according to a second embodiment of the present disclosure

### <1. Problem of a Semiconductor Laser Element>

### [Step Generated in ITO Layer]

In a semiconductor laser element 100, a step may be generated in an ITO layer 5 of a front end surface 12 or a rear end surface 13 when a wafer is cleaved.

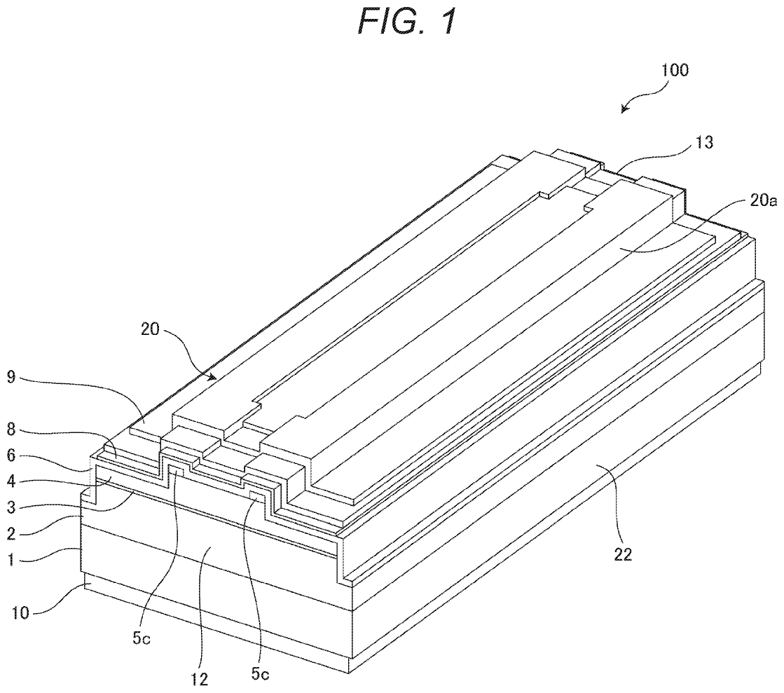

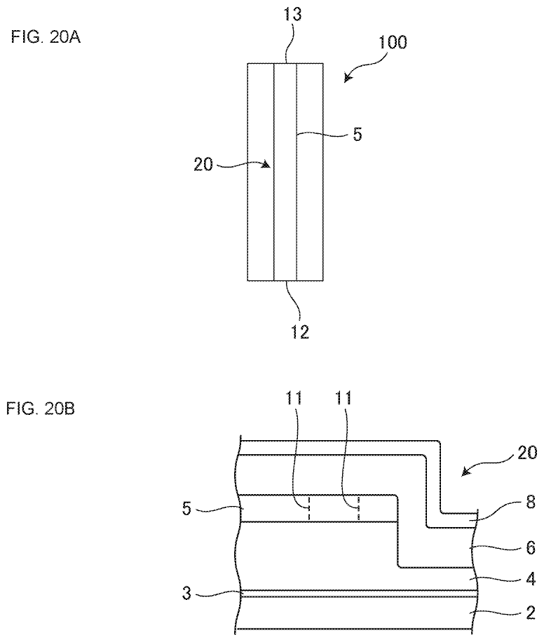

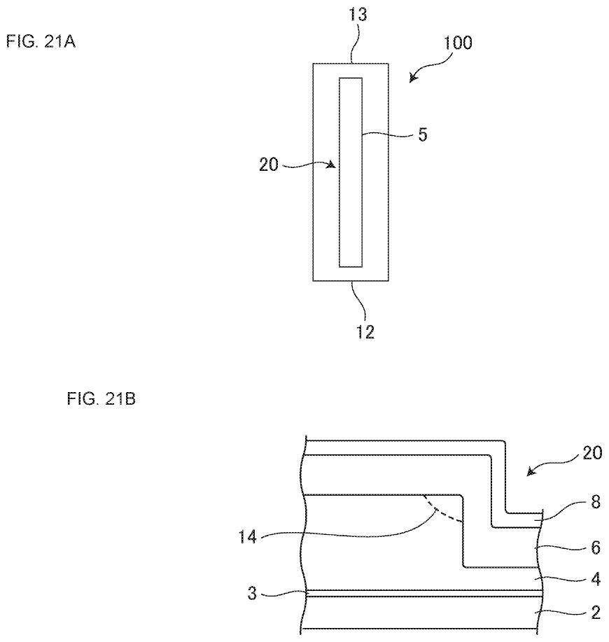

This will be described in more detail below with reference to FIGS. 1 to 5. FIG. 20A is a schematic plan view of an example of the semiconductor laser element 100. In this drawing, the ITO layer 5 is formed on an entire surface of a ridge portion 20 from the front end surface 12 to the rear end surface 13. FIG. 20B is a schematic diagram of steps 11 generated in the ITO layer 5 of the semiconductor laser element 100 formed as shown in FIG. 20A as viewed from the front end surface 12 side.

As indicated by broken lines in FIG. 20B, a plurality of the steps 11 is generated in a longitudinal direction in the ITO layer 5. Such generation of the steps 11 in the ITO layer 5 located in the vicinity of an active layer 3 that generates laser light can affect optical characteristics of the semiconductor laser element 100. Furthermore, when the steps 11 extend from the steps 11 as starting points, there is a possibility of causing failure of the semiconductor laser element 100. Therefore, the generation of the steps 11 needs to be avoided.

The above steps 11 are generated because the laminated ITO layer 5 has a strong stress. The stress of the ITO layer 5 is generated in a process in which evaporated atoms and molecules adhere to the substrate and are condensed in a lamination process, and remains as residual stress inside even after the lamination of the ITO layer 5.

Furthermore, a factor of generation of the steps 11 is considered to be that an excessive force is applied to the ridge portion 20 as compared with other portions in a cleavage process, and this acts as a trigger for generation of the steps 11.

However, since the ridge portion 20 protrudes in the semiconductor laser element 100, a thickness changes between a part of the ridge portion 20 and parts other than the ridge portion 20 in the cleavage process. For this reason, the protruding ridge portion 20 receives an excessive force as compared with other portions at the time of cleavage. It is considered that receiving such a force triggers generation of the steps 11.

### [About Crack Generated on ITO Side Band on Upper Surface of ITO Layer]

As described above, in the semiconductor laser element 100, a crack 14 may be generated on an edge of the semiconductor portion of the front end surface 12 and the rear end surface 13 of an upper surface 4a of the nitride semiconductor layer 4 of the second conductivity type configuring the ridge portion 20 at the time of cleavage of the wafer (not shown).

This will be described in more detail. FIG. 21A is a schematic plan view of the semiconductor laser element 100 in which the ITO layer 5 is not formed in a region of a predetermined length from the front end surface 12 and the rear end surface 13 of the semiconductor laser element 100 as a measure for preventing the steps 11 from being generated. The ITO layer 5 is formed as shown in this figure, so that it could be confirmed that no steps 11 has been generated.

However, there is a problem that the crack 14 is generated on the edge of the semiconductor portion of the front end surface 12 and the rear end surface 13. FIG. 21B is a schematic diagram of the crack 14 generated at the edge of the nitride semiconductor layer 4 of the second conductivity type of the semiconductor laser element 100 formed as shown in FIG. 21A as viewed from the front end surface 12 side. The crack 14 is indicated by a broken line in FIG. 21B. Note that, since FIG. 21B is the schematic diagram of FIG. 21A, the ITO layer 5 is not laminated on a portion where the crack 14 is generated in the nitride semiconductor layer 4 of the second conductivity type.

The semiconductor laser elements 100 are arranged and formed on a wafer. Therefore, in order to cleave the wafer, the cleavage proceeds in a direction perpendicular to a longitudinal direction of the semiconductor laser element 100. However, similarly to the above, since the ridge portion 20 protrudes in the semiconductor laser element 100, a thickness changes between a part of the ridge portion 20 and parts other than the ridge portion 20 during the progress of cleavage. For this reason, the ridge portion 20 receives an excessive force as compared with other portions during the progress of cleavage.

As a result, it is considered that the crack 14 is generated on the edge of the semiconductor portion of the front end surface 12 and the rear end surface 13 of the upper surface 4a of the nitride semiconductor layer 4 of the second conductivity type in the ridge portion 20.

The present disclosure suppresses the generation of the steps 11 and the generation of the crack 14 in the ITO layer 5.

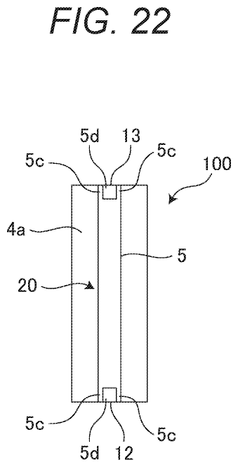

In order to solve such a problem, as shown in the schematic plan view of FIG. 22, there has been manufactured and tested a semiconductor laser element 100 having a structure in which band-shaped ITO side bands 5c and 5c are extended toward both end surfaces of the front end surface 12 and the rear end surface 13 on the upper surface 4a of the nitride semiconductor layer 4 of the second conductivity type, the ITO layer 5 in rectangular regions sandwiched between both the ITO side bands 5c and 5c is cut off, and each of the ITO removal regions 5d and 5d is in contact with the front end surface 12 or the rear end surface 13. As a result, the steps 11 and the crack 14 are not generated, and improvement effects could be confirmed.

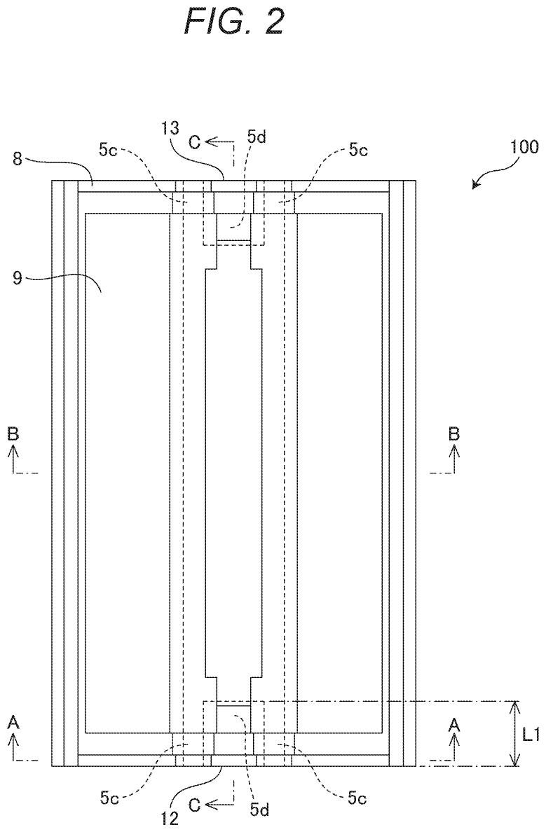

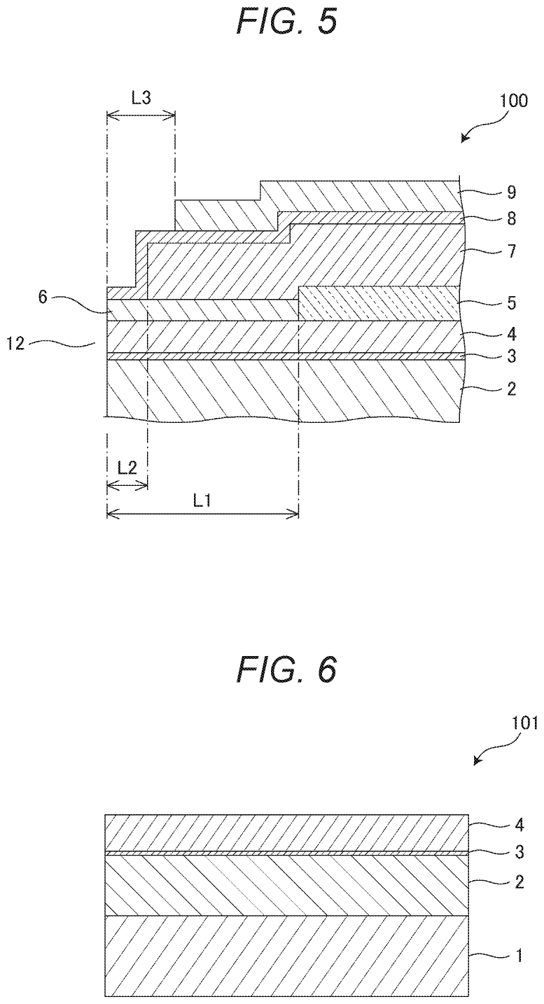

Based on the above examination results and test results, the ITO layer 5 is configured not to be formed in predetermined regions on the upper surface 4a of the nitride semiconductor layer 4 of the second conductivity type in predetermined regions from the front end surface 12 and the rear end surface 13 as shown in FIGS. 2 and 5. Specifically, in a section of a length L1 from each of the front end surface 12 and the rear end surface 13, band-shaped ITO side bands 5c and 5c are extended toward both end surfaces at both side ends of the upper surface 4a of the nitride semiconductor layer 4 of the second conductivity type, and the region sandwiched between the ITO side bands 5c and 5c is configured to form the ITO removal region 5d in which the ITO layer 5 is removed in a rectangular shape.

Note that the details will be described later.

### <2. Semiconductor Laser Element According to a First Embodiment of the Present Disclosure>

Hereinafter, a semiconductor laser element 100 according to a first embodiment of the present disclosure will be described with reference to FIGS. 1 to 5. As shown in an external perspective view of FIG. 1, the semiconductor laser element 100 according to the present disclosure is formed in an elongated substantially rectangular shape. Then, a ridge portion 20 having a ridge shape extends on the upper surface along a longitudinal direction, that is, a direction of a resonator.

The ridge portion 20 is formed by removing both side surfaces of a nitride semiconductor layer 4 of a second conductivity type by etching such as RIE. A width (direction orthogonal to the resonator direction) of the ridge portion 20 is, for example, 500 nm to 100 μm, and is, for example, 40 μm in the case of a manufactured product (hereinafter, referred to as a “production example”) in the present embodiment shown in FIG. 1. A region sandwiched between the front end surface 12 and the rear end surface 13 of the semiconductor laser element 100 forms a reflector. That is, a resonator that amplifies light by reciprocating laser light between the front end surface 12 and the rear end surface 13 is configured. A distance (resonator length) between the front end surface 12 and the rear end surface 13 is, for example, 50 μm to 3000 μm, and is 1200 μm in the production example of the present embodiment.

Both side walls 20a and 20a of the ridge portion 20 are covered with an insulating layer 6. In the present production example, it includes silicon dioxide (SiO₂) and silicon nitride (Si₃N₄), and the film thickness is, for example, 10 nm to 500 nm, and 200 nm in the present production example.

The semiconductor laser element 100 is configured by, for example, a laminating a nitride semiconductor layer 2 of a first conductivity type, an active layer 3, a nitride semiconductor layer 4 of a second conductivity type, an ITO layer 5, an insulating layer 6, a pad metal layer 7, a barrier metal layer 8, and a bonding metal layer 9 on an n-type GaN substrate 1. Then, a first electrode 10 such as a cathode for electrical connection is disposed below the n-type GaN substrate 1. Note that in a case where the “first conductivity type” is n-type, a “second conductivity type” is p-type, and in a case where the “first conductivity type” is p-type, the “second conductivity type” is n-type. In the following embodiment, a description will be given assuming that the “first conductivity type” is the n-type and the “second conductivity type” is the p-type.

The n-type GaN substrate 1 forms a base for laminating each layer configuring the semiconductor laser element 100.

The nitride semiconductor layer 2 of the first conductivity type includes, for example, a cladding layer of the first conductivity type having a low refractive index and a guide layer of the first conductivity type having an intermediate refractive index between the cladding layer of the first conductivity type and the active layer 3 in order to confine light emitted from the active layer 3 described later.

The active layer 3 is a region that emits light having a wavelength corresponding to a band gap by recombination of electrons and holes. The active layer 3 may have a multi-quantum well (MQW: multi-quantum well) structure in addition to a quantum well (quantum well) structure. With the formation of the active layer 3 in the multi-quantum well structure, the number of layers that emit light increases, so that a light emission intensity of the laser can be improved.

The nitride semiconductor layer 4 of the second conductivity type may include, for example, a guide layer of the second conductivity type corresponding to the guide layer of the first conductivity type that confines light due to a difference in refractive index, a cladding layer of the second conductivity type corresponding to the cladding layer of the first conductivity type, and a contact layer of a low resistance value for making ohmic contact with an electrode. Furthermore, an electron barrier layer for blocking electrons overflowing beyond the active layer 3 may be formed.

The ITO layer 5 is, for example, a colorless and transparent substance forming a second electrode such as an anode of the semiconductor laser element 100, and is an inorganic mixture of group III indium oxide (In₂O₃) and group IV tin oxide (SnO₂) as described above. Since the ITO layer 5 has high transmittance in a visible light region, the ITO layer 5 is almost colorless and transparent in a thin film. Therefore, light loss is small, and heat generation due to light absorption does not occur. Furthermore, its melting point is as extremely high as 1800 to 2200 K, it is a good electrical conductor, and the second electrode is close in distance to the active layer 3, and is therefore suitable as an electrode of the semiconductor laser element 100.

As shown in FIGS. 1 to 5, the ITO layer 5 is laminated on the entire surface of the ridge portion 20 excluding the predetermined regions from the front end surface 12 and the rear end surface 13 on the upper surface 4a of the nitride semiconductor layer 4 of the second conductivity type.

That is, the ITO layer 5 in the section of the length L1 from each of the front end surface 12 and the rear end surface 13, the band-shaped ITO side bands 5c and 5c are extended toward both end surfaces at both side ends of the upper surface 4a of the nitride semiconductor layer 4 of the second conductivity type, and the region sandwiched between the ITO side bands 5c and 5c forms the ITO removal region 5d. Therefore, the ITO layer 5 on the front end surface 12 side and the rear end surface 13 side is formed in a substantially C shape or a U shape as a whole in plan view. Furthermore, an inside of the ITO removal region 5d is covered with the insulating layer 6. In the present production example, a width of the ITO side band 5c is set to 1 μm since the effect is observed at 0.5˜5 μm and is preferably 1 μm.

The insulating layer 6 covers the upper surface 4a of the nitride semiconductor layer 4 of the second conductivity type and the upper surface 5a of the ITO layer 5 to maintain insulation. As described above, the insulating layer 6 includes silicon dioxide (SiO₂) and silicon nitride (Si₃N₄), and has a film thickness of, for example, 10 nm to 500 nm, and 200 nm in the present production example. Although not shown in FIGS. 1 to 5, resistance of the nitride semiconductor layer 4 of the second conductivity type in a region from the side wall 20a of the ridge portion 20 to the side surface portion 22 of the semiconductor laser element 100 except for a metal connection region 5e of the ITO layer 5 of the ridge portion 20 to which current injection is performed is increased by injection of boron (B) ions or the like.

The pad metal layer 7 is a wiring layer including titanium (Ti), platinum (Pt), palladium (Pd), nickel (Ni), gold (Au), or the like which is electrically connected to the ITO layer 5 and has a heat dissipation function for performing interconnection between the ITO layer 5 and the bonding metal layer 9.

The barrier metal layer 8 is a metal film for suppressing diffusion of tin (Sn) or the like from solder used for mounting, and includes, for example, titanium (Ti), platinum (Pt), molybdenum (Mo), tungsten (W), or the like.

The bonding metal layer 9 is eutectically bonded to a submount (not shown) by junction down.

Furthermore, as shown in FIG. 5, on the upper surfaces of the ITO layer 5 and the insulating layer 6, a section of a length L2 from the front end surface 12 is covered only with the barrier metal layer 8. Furthermore, a section of a length L3 excluding the length L2 is covered with the pad metal layer 7 and the barrier metal layer 8. Furthermore, a section longer than the length L3 is covered with the pad metal layer 7, the barrier metal layer 8, and the bonding metal layer 9. On the other hand, in a section longer than the length L1, the metal connection region 5e of the ITO layer 5 is not covered with the insulating layer 6 as shown in FIG. 4. Therefore, the ITO layer 5 and the pad metal layer 7 are electrically connected in the metal connection region 5e.

As a result of performing a reliability test and the like on the semiconductor laser element 100 configured as described above, it has been confirmed that the generation of the steps 11 is suppressed and the reliability can be improved as described above with reference to FIG. 22.

At the same time, it has been also confirmed that the effect of suppressing the generation of the crack 14 on the edge of the semiconductor portion of the front end surface 12 and the rear end surface 13 of the upper surface 4a of the nitride semiconductor layer 4 of the second conductivity type of the ridge portion 20 generated at the time of cleavage can be obtained.

The reason why the above improvement can be achieved is considered as follows with respect to the generation of the steps 11. That is, in the ITO layer 5, the band-shaped ITO side bands 5c and 5c are extended toward both end surfaces at both side ends, and a region sandwiched between the ITO side bands 5c and 5c forms the ITO removal region 5d.

It is considered that a stress of the ITO layer 5 has been absorbed by forming the ITO layer 5 in a substantially C-shape or a substantially U-shape in plan view. That is, this is because an internal stress of the ITO layer 5 can be absorbed by dividing the surfaces in contact with the front end surface 12 and the rear end surface 13 rather than covering and forming the entire upper surface 4a of the nitride semiconductor layer 4 of the second conductivity type.

Furthermore, the reason why the generation of the crack 14 is suppressed is considered to be that the edge of the semiconductor portion where the crack 14 is likely to be generated at the time of cleavage is protected by being covered with the band-shaped ITO side bands 5c and 5c extending on both side ends of the upper surface 4a of the nitride semiconductor layer 4 of the second conductivity type.

According to the semiconductor laser element 100 of the first embodiment of the present disclosure, with the configuration described above, there can be provided a semiconductor laser element 100 with improved reliability and yield by suppressing the generation of the steps 11 in the ITO layer 5 or the semiconductor portion in contact with the ITO layer 5 at the time of cleavage of a wafer, and the generation of the crack 14 in an edge of a semiconductor portion of the front end surface 12 and the rear end surface 13 on the upper surface 4a of the nitride semiconductor layer 4 of the second conductivity type.

### <3. Method for Manufacturing a Semiconductor Laser Element According to the First Embodiment of the Present Disclosure>

### [Process of Manufacturing Wafer of the Semiconductor Laser Element]

Hereinafter, a method for manufacturing the semiconductor laser element 100 according to the first embodiment of the present disclosure will be described with reference to a process of manufacturing a wafer of the semiconductor laser element 100.

First, a wafer of n-type GaN substrate 1 for forming the semiconductor laser element 100 by lamination is prepared. Note that although one semiconductor laser element 100 will be described below, in fact, a large number of semiconductor laser elements 100 are regularly arranged in a lattice pattern in a wafer. Furthermore, FIGS. 6 to 8, 10, 11, and 13 to 16 are views of the semiconductor laser element 100 or a laminated structure 101 to be described later as viewed from the front end surface 12 side which is a light emission end surface.

When a wafer of the n-type GaN substrate 1 is prepared, as shown in FIG. 6, the nitride semiconductor layer 2 of the first conductivity type is laminated on the n-type GaN substrate 1 by, for example, a metal organic chemical vapor deposition (MOCVD: Metal Organic Chemical Vapor Deposition) method.

Next, the active layer 3 is laminated on the nitride semiconductor layer 2 of the first conductivity type. Here, the nitride semiconductor layer 2 of the first conductivity type is, for example, an AlxGa (1-x-y) InyN (x≥0, y≥0, x+y≤1) layer, and may include the cladding layer of the first conductivity type and the guide layer of the first conductivity type as described above.

Next, the nitride semiconductor layer 4 of the second conductivity type is laminated on the active layer 3. Here, the nitride semiconductor layer 4 of the second conductivity type is, for example, an AlxGa (1-x-y) InyN (x≥0, y≥0, x+y≤1) layer, and may include the guide layer of the second conductivity type, the cladding layer of the second conductivity type, and the contact layer as described above. Each layer is laminated in this manner to form the laminated structure 101. Note that, in the present specification, the laminated structure 101 refers to the semiconductor laser element 100 being formed by laminating the nitride semiconductor layer and the like.

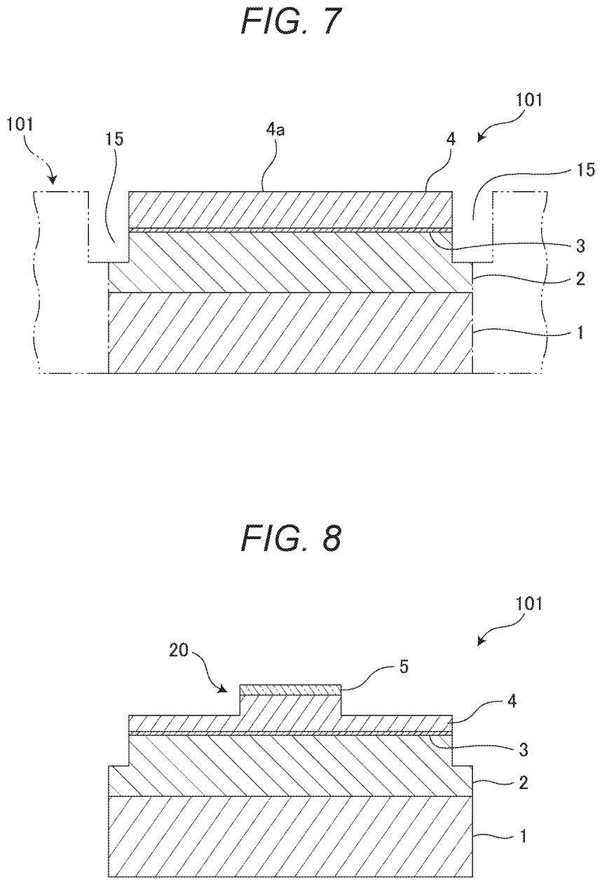

Next, one laminated structure 101 and the other laminated structure 101 are separated. That is, as shown in FIG. 7, the laminated structures 101 and 101 are separated from each other by forming grooves 15 extending to the nitride semiconductor layer 4 of the second conductivity type, the active layer 3, and the nitride semiconductor layer 2 of the first conductivity type along the longitudinal direction. As a method of forming the grooves 15, for example, an etching mask layer (not shown) including SiO₂, Si₃N₄, or the like is formed on the upper surface 4a of the nitride semiconductor layer 4 of the second conductivity type by a vapor deposition method, a sputtering method, or the like. The etching mask layer is subjected to pattern formation using photolithography, and the etching mask layer at a resist opening is removed by the RIE method using a fluorine-based gas or hydrofluoric acid-based wet etching.

Next, as shown in FIG. 7, the nitride semiconductor layer 4 of the second conductivity type is etched by the RIE method using a chlorine-based gas, and the laminated structure is removed up to reaching the nitride semiconductor layer 2 of the first conductivity type.

Next, the ridge portion 20 and the ITO layer 5 are formed. That is, the ITO layer 5 is uniformly laminated on the upper surface 4a of the nitride semiconductor layer 4 of the second conductivity type by, for example, a vapor deposition method, a sputtering method, or the like. In addition to the ITO layer 5, examples of a material forming the transparent conductive film include indium titanium oxide (ITiO: Indium Titanium Oxide), aluminum oxide-doped zinc oxide (AZO: Al₂O₃—ZnO), IGZO (InGaZnOx: abbreviation of a substance composed of indium In, gallium Ga, zinc Zn, and oxygen Ox), and so on.

Next, as shown in FIG. 8, a center portion in the longitudinal direction (resonator direction) of the ITO layer 5 and the nitride semiconductor layer 4 of the second conductivity type laminated on the upper surface of the laminated structure 101 are left, and both sides thereof are removed by etching such as RIE. Specifically, the contact layer of the nitride semiconductor layer 4 of the second conductivity type and a part of the upper portion of the cladding layer of the second conductivity type are removed.

As a result, a convex ridge portion 20 is formed on the laminated structure 101 formed by lamination. The ridge portion 20 extends in a longitudinal direction (resonator direction), that is, in a backward direction as viewed from the drawing.

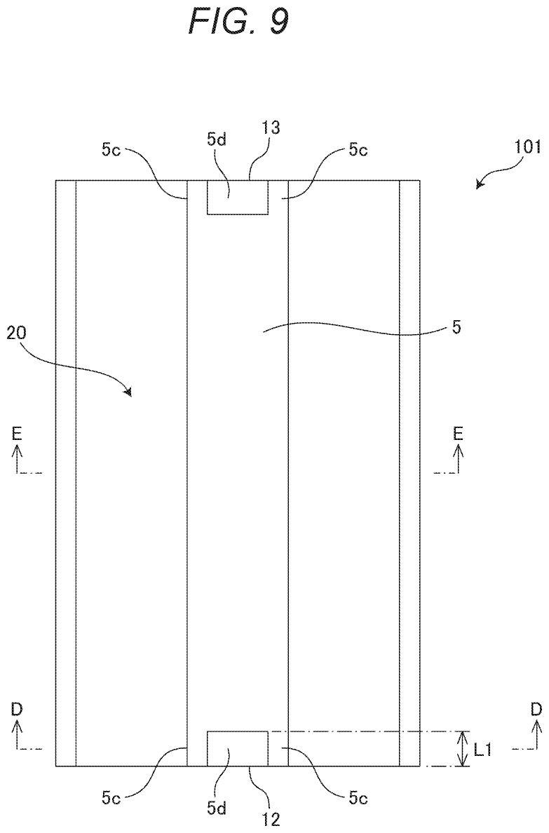

Next, as shown in FIG. 9, the ITO side bands 5c and 5c and the ITO removal regions 5d are formed in the ITO layer 5 forming the ridge portion 20. Specifically, in the region of the length L1 from each of the front end surface 12 and the rear end surface 13 of the laminated structure 101, the band-shaped ITO side bands 5c and 5c are formed at both side ends, and the ITO layer 5 of the region sandwiched between the ITO side bands 5c and 5c is removed to form the ITO removal region 5d having a substantially rectangular shape in plan view. Therefore, the length of the ITO removal region 5d is L1. Furthermore, the width is a dimension obtained by removing the widths of the ITO side bands 5c and 5c from the width of the ITO layer 5. As a result, the ITO layer 5 is formed in a substantially C-shape or a substantially U-shape in plan view in the vicinity of both end surfaces.

Such processing is performed as follows. First, an etching mask layer (not shown) including, for example, SiO₂, Si₃N₄, or the like is formed on the ITO layer 5 laminated on the upper surface of the ridge portion 20 by a vapor deposition method, a sputtering method, or the like. The etching mask layer is patterned using photolithography, and the etching mask layer at a resist opening is removed by the RIE method using a fluorine-based gas or hydrofluoric acid-based wet etching.

Next, as shown in FIG. 9, the ITO removal region 5d is removed by RIE using a chlorine-based gas while leaving the band-shaped ITO side bands 5c and 5c at both side ends of the ITO layer 5 in the portion of the length L1 from each of the front end surface 12 and the rear end surface 13 of the laminated structure 101.

As a result, the ITO layer 5 on the front end surface 12 side and the rear end surface 13 side is formed in a substantially C-shape or a U-shape as a whole in plan view.

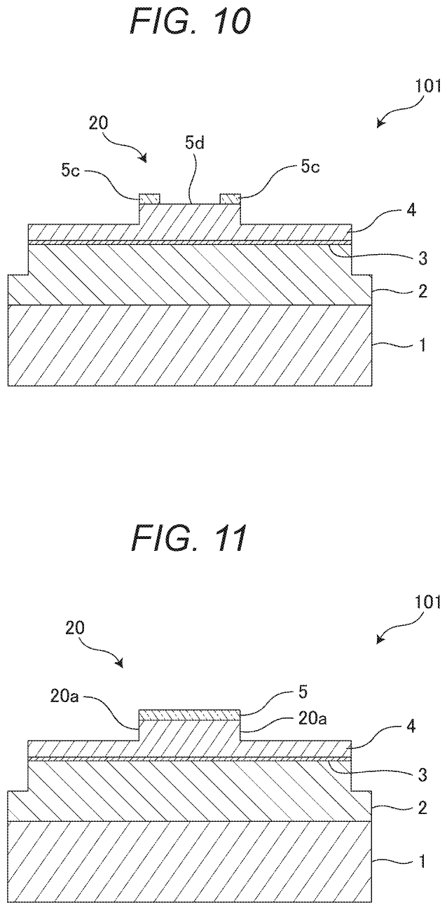

FIG. 10 shows a cross-sectional view taken along line D-D of the laminated structure 101 in FIG. 9 formed in this manner. FIG. 11 is a cross-sectional view taken along line E-E in the same manner.

Furthermore, instead of removing the ITO removal region 5d from the ITO layer 5, a pattern, a character, or a symbol such as a substantially saw pattern, a ladder pattern, a checkered pattern, or a substantially zigzag lattice pattern, or a combination thereof may be formed in the ITO removal region 5d.

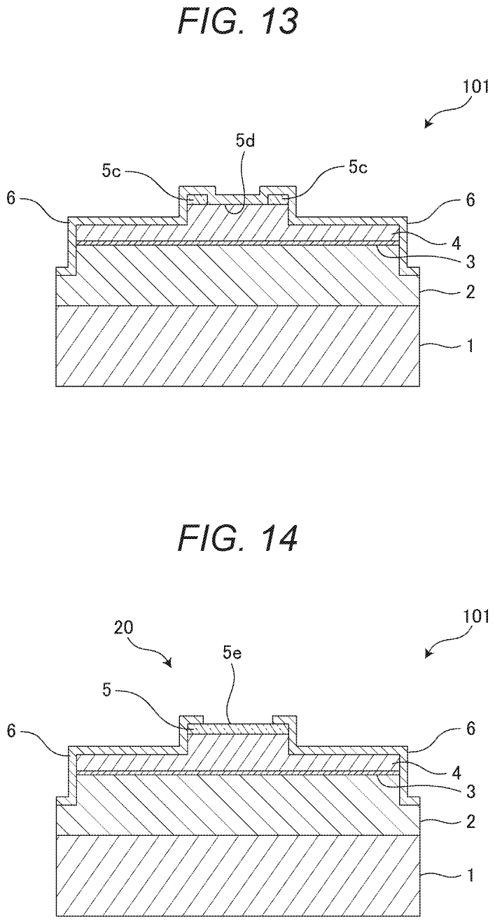

Next, as shown in FIGS. 13 and 14, the insulating layer 6 is formed on the upper surface of the laminated structure 101 and the side wall 20a of the ridge portion 20 by a vapor deposition method, a sputtering method, or the like. Specifically, the insulating layer 6 including SiO₂, Si₃N₄, or the like is formed by a vapor deposition method, a sputtering method, or the like. The insulating layer 6 is patterned by photolithography.

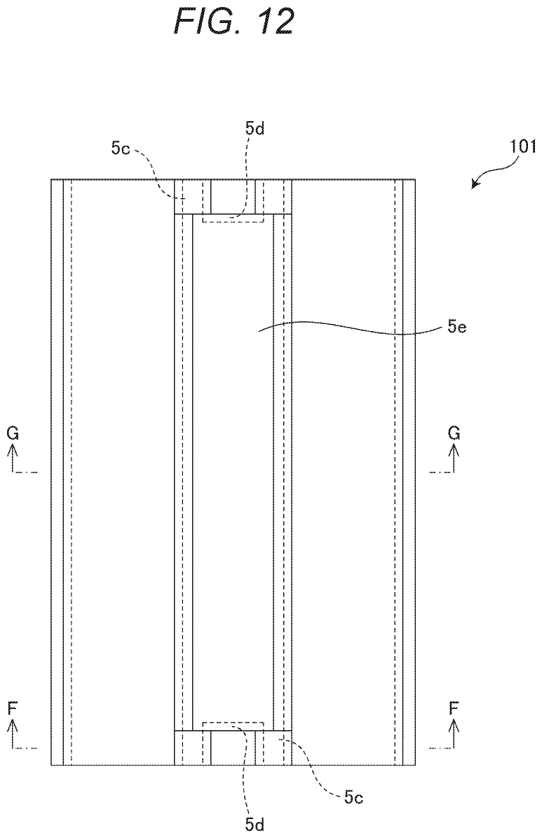

Next, the insulating layer 6 at a resist opening is removed by a RIE method using a fluorine-based gas or hydrofluoric acid-based wet etching. As a result, the metal connection region 5e is formed on the ITO layer 5. A second electrode is formed on the metal connection region 5e in a next process to enable electrical connection. FIG. 13 shows a cross-sectional view taken along line F-F of the laminated structure 101 formed in this manner in FIG. 12. Similarly, FIG. 14 shows a cross-sectional view taken along line G-G.

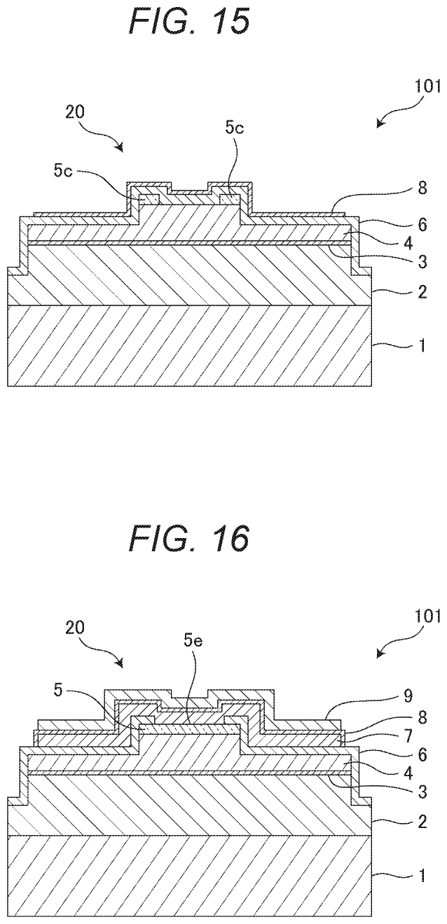

Next, as shown in FIGS. 15 and 16, a second electrode including the pad metal layer 7, the barrier metal layer 8, and the bonding metal layer 9 is formed on the upper surface of the laminated structure 101.

Each of the metal layers 7, 8, and 9 is formed by a vapor deposition method, a sputtering method, or the like, and a pattern is formed by a lift-off method, for example.

When each of the thick metal layers 7, 8, and 9 is provided on the cleavage line to be the front end surface 12 and the rear end surface 13, a problem occurs in which a highly ductile metal extends at the time of cleavage and hangs down to a front surface of the active layer 3 to hinder light emission. For this reason, as shown in FIGS. 5 and 15, only the barrier metal layer 8 having a small thickness is laminated in the section having the length L2 on the cleavage line. Furthermore, a section of the length L3 excluding the length L2, the pad metal layer 7 and the barrier metal layer 8 are laminated. Furthermore, in the section longer than the length L3, as shown in FIGS. 5 and 16, each metal layer of the pad metal layer 7, the barrier metal layer 8, and the bonding metal layer 9 is laminated in order to secure heat dissipation. With this configuration, a structure is obtained in which the pad metal layer 7 and the bonding metal layer 9 are not covered on the cleavage line to be the front end surface 12 and the rear end surface 13.

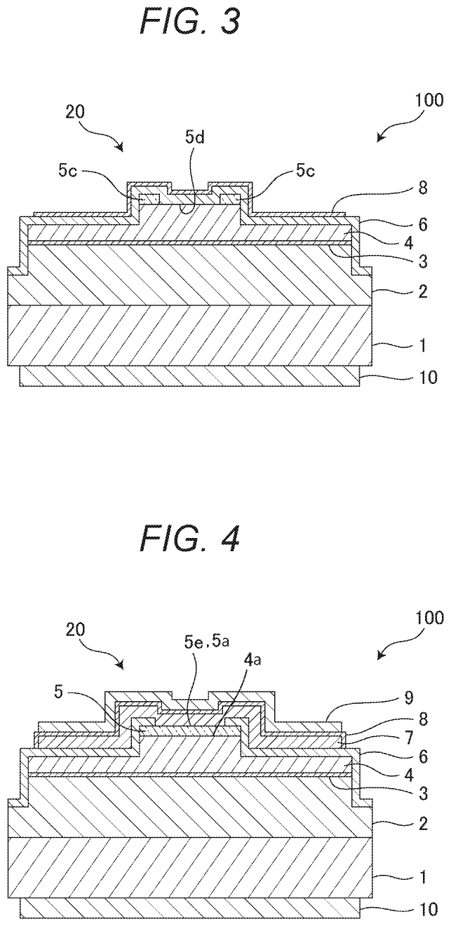

Next, a back surface of the laminated structure 101 is polished so as to have a thickness suitable for cleavage and mounting. When the polishing has been completed, an n-metal film is formed on the back surface by a vapor deposition method, a sputtering method, or the like, a pattern is formed by, for example, a lift-off method, and an n-electrode 10 is formed as shown in FIGS. 3 and 4.

As described above, the wafer of the semiconductor laser element 100 is formed.

### [Cleaving, Mounting, and Inspection Process of Wafer of Semiconductor Laser Element]

Next, the wafer is cleaved in a cleaving process, inspected in an inspection process, and selected as a good product or a defective product. The nitride semiconductor light-emitting element 100 selected as the good product by the inspection is sent to a mounting process which is a next process. The nitride semiconductor light-emitting element 100 is packaged in the mounting process and finally inspected. In this way, the nitride semiconductor light-emitting element 100 according to the present embodiment can be manufactured.

Since the method for manufacturing the semiconductor laser element 100 according to the first embodiment of the present disclosure includes the above-described processes, and therefore can provide the semiconductor laser element 100 with high quality according to the present embodiment.

### <4. Semiconductor Laser Element According to a Second Embodiment of the Present Disclosure>

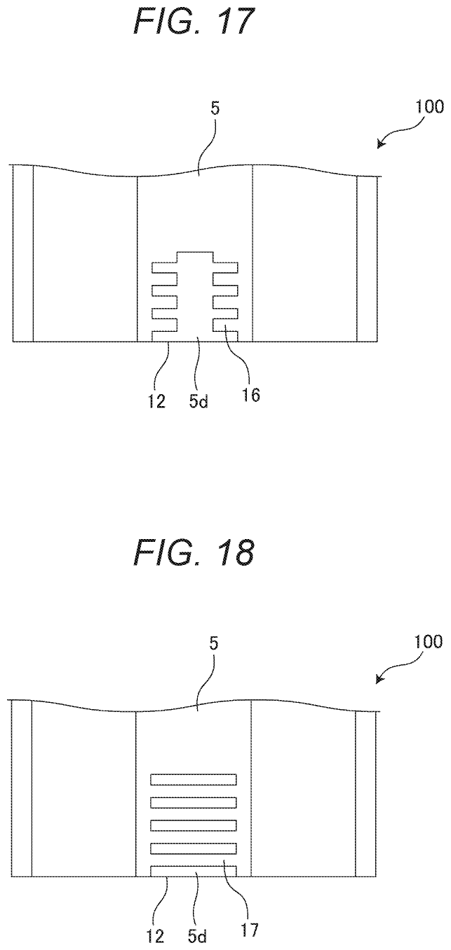

Next, a semiconductor laser element 100 according to a second embodiment of the present disclosure will be described with reference to FIGS. 17 to 19. The semiconductor laser element 100 according to the present embodiment is different from that of the first embodiment in that a shape of the ITO removal region 5d of the ITO layer 5 is formed not in a rectangular shape but in a substantially sawtooth pattern, a substantially ladder pattern, a checkered pattern, or a zigzag lattice pattern.

### First Configuration Example

Hereinafter, a first configuration example of the second embodiment will be described. FIG. 17 shows an example in which an inside of a region of an ITO removal region 5d of a ITO layer 5 is formed in a substantially saw pattern. Specifically, in the rectangular ITO removal region 5d in the first embodiment, three protrusions 16 each having a predetermined rectangular length protrude in a front-back direction from a left and right direction of the ITO removal region 5d in the drawing, and the left and right sides are formed in a substantially saw pattern.

Note that, in the present configuration example, the three rectangular protrusions 16 are provided bilaterally symmetrically, but is not limited to the bilateral symmetry, and for example, the protrusions may be provided alternately. Further, the number is not limited to three. Furthermore, the protruding length may be arbitrarily determined, and the protruding length may be different for each protrusion 16.

### Second Configuration Example

Next, a second configuration example of the second embodiment will be described. FIG. 18 shows an example in which an inside of a region of an ITO removal region 5d of a ITO layer 5 is formed in a substantially ladder pattern. Specifically, in the rectangular ITO removal region 5d in the first embodiment, the ITO removal region 5d in this drawing is connected in the left-right direction by bars 17 to form the substantially ladder pattern.

Note that, in this configuration example, bars 17 are connected at three positions on the left and right, but the number of positions is not limited to three. Furthermore, the width and interval of the bars 17 may be arbitrarily determined, and the bars 17 may have a curved shape instead of a straight line. Furthermore, the shape may be diagonal, and may be substantially rhombic, substantially mortar, or substantially drum.

### Third Configuration Example

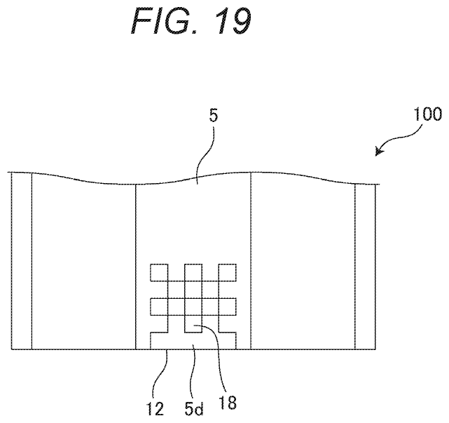

Next, a third configuration example of the present embodiment will be described. FIG. 19 shows an example in which the inside of the region of the ITO removal region 5d of the ITO layer 5 is formed in a checkered pattern or a substantially zigzag lattice pattern. Specifically, in the rectangular ITO removal region 5d in the first embodiment, the ITO removal region 5d in this drawing is formed in the checkered pattern or the substantially zigzag lattice pattern.

Note that, in the present configuration example, five squares 18 are formed in each of the front-back, left-right directions, but the number is not limited to five. Furthermore, the size of the squares 18 may also be arbitrarily determined. Furthermore, the squares 18 may have a rectangular shape or a rhombic shape instead of a square shape.

### Other Configuration Examples

Further, other configuration examples of the second embodiment will be described. The shape of the ITO removal region 5d in the second embodiment is not limited to the above examples, and for example, information such as characters and numbers may be patterned. Furthermore, symbols or the like indicating orientations and directions such as arrows may be patterned. Furthermore, it may be a barcode.

Furthermore, in the ITO removal region 5d in the present embodiment, the pattern, the character symbol, and the like on the front end surface 12 side may be different from the pattern, the character symbol, and the like on the rear end surface 13 side.

With the combination of different patterns, character symbols, and the like in this manner, for example, a pattern or the like on the front end surface 12 side and a pattern or the like on the rear end surface 13 side are made different from each other, to make it easy to identify both sides. This makes it possible to prevent human error and recognize a pattern in an inspection process, which can contribute to quality improvement and cost reduction.

Other configurations are similar to those of the first embodiment, and thus a description thereof will be omitted.

Since the present embodiment is configured as described above, the ITO layer 5 and the nitride semiconductor layer 4 of the second conductivity type are electrically connected also in the ITO removal region 5d. For this reason, since a conduction area can be widened as compared with the first embodiment, an electric resistance can be reduced.

Furthermore, since the insulating layer 6 is also embedded in the ITO layer 5 formed with, for example, a substantially saw-shaped complicated pattern formed in the ITO removal region 5d, and the barrier metal layer 8 is further laminated thereon, adhesion with the barrier metal layer 8 and the like is improved. This makes it possible to prevent peeling of the pad metal layer 7 and the like laminated on the upper surface 5a of the ITO layer 5.

Furthermore, the pattern is formed as described above, so that the front end surface 12 and the rear end surface 13 can be distinguished from each other, and human errors in a mounting process, a material handling process, and the like can be prevented. Furthermore, it can be used as a reference pattern for pattern matching and appearance inspection at the time of a subsequent process, to make it possible to reliably improve the quality and reduce the cost.

As described above, according to the second embodiment, quality improvement can be realized by providing the pad metal layer 7 or the like with the functions of the prevention of peeling and identification, in addition to the prevention of the generation of the steps 11 and the prevention of the generation of the crack 14 in the first embodiment.

Finally, the description of each of the above-described embodiments is an example of the present disclosure, and the present disclosure is not limited to the above-described embodiments. For this reason, it is needless to say that various modifications other than the above-described each embodiment can be made according to the design and the like without departing from the technical idea according to the present disclosure. Furthermore, the effects described in the present specification are merely examples and are not limited to them, and other effects may be further provided.

Note that the present technology can also have the following configuration.
(1)
A semiconductor laser element including:
a GaN substrate;
a nitride semiconductor layer of a first conductivity type laminated on the GaN substrate;
an active layer laminated on the nitride semiconductor layer of the first conductivity type;
a nitride semiconductor layer of a second conductivity type laminated on the active layer and formed in a ridge waveguide structure;
transparent conductive film side bands laminated on the nitride semiconductor layer of the second conductivity type and extending in a band shape along a longitudinal direction toward both end surfaces;
a transparent conductive film provided continuously with the transparent conductive film side bands, laminated on the nitride semiconductor layer of the second conductivity type, and formed with each of regions sandwiched between the transparent conductive film side bands and cut in a rectangular shape to be in contact with the end surfaces;
an insulating layer laminated on the transparent conductive film; and
a metal layer laminated on the insulating layer.
(2)
The semiconductor laser element according to the above (1), in which the nitride semiconductor layer of the first conductivity type includes a cladding layer and a guide layer.
(3)
The semiconductor laser element according to the above (1) or (2), in which the nitride semiconductor layer of the second conductivity type includes a cladding layer and a guide layer.
(4)
The semiconductor laser element according to any one of the above (1) to (3), in which
the metal layer includes a pad metal layer, a barrier metal layer, and a bonding metal layer.
(5)
The semiconductor laser element according to the above (4), in which the metal layer laminated on a cleavage line to be a front end surface and a rear end surface is a barrier metal layer.
(6)
The semiconductor laser element according to any one of the above (1) to (4), in which the transparent conductive film includes indium tin oxide (ITO), indium titanium oxide (ITiO), aluminum oxide-doped zinc oxide (AZO), or IGZO (InGaZnOx).
(7)
The semiconductor laser element according to any one of (1) to (4) or (6), in which a region of the transparent conductive film sandwiched between the transparent conductive film side bands and cut in a rectangular shape is covered with an insulating layer.
(8)
The semiconductor laser element according to any one of the above (1) to (4) or (6), in which the transparent conductive film formed in a pattern, a character, a symbol, or a combination thereof is disposed in the region of the transparent conductive film sandwiched between the transparent conductive film side bands and cut into the rectangular shape.
(9)
The semiconductor laser element according to any one of the above (1) to (4), (6) or (8), in which the pattern, the character, the symbol, or the combination thereof of the transparent conductive film formed in the region of the transparent conductive film sandwiched between the transparent conductive film side bands and cut into the rectangular shape is different between the front end surface and the rear end surface.

### REFERENCE SIGNS LIST

1 GaN substrate
2 nitride semiconductor layer of first conductivity type
3 active layer
4 nitride semiconductor layer of second conductivity type
4a upper surface of nitride semiconductor layer of second conductivity type
5 ITO layer
5a upper surface of ITO layer
5c ITO side band
5d ITO removal region
5e metal connection region
6 insulating layer
7 pad metal layer
8 barrier metal layer
9 bonding metal layer
10 first electrode
11 step
12 front end surface
13 rear end surface
14 crack
15 groove
16 protrusion
17 bar
18 square
20 ridge portion
20a side wall
22 side surface portion
100 semiconductor laser element
101 laminated structure
L1, L2, L3 length

1. A semiconductor laser element comprising:
a GaN substrate;
a nitride semiconductor layer of a first conductivity type laminated on the GaN substrate;
an active layer laminated on the nitride semiconductor layer of the first conductivity type;
a nitride semiconductor layer of a second conductivity type laminated on the active layer and formed in a ridge waveguide structure;
transparent conductive film side bands laminated on the nitride semiconductor layer of the second conductivity type and extending in a band shape along a longitudinal direction toward both end surfaces;
a transparent conductive film provided continuously with the transparent conductive film side bands, laminated on the nitride semiconductor layer of the second conductivity type, and formed with each of regions sandwiched between the transparent conductive film side bands and cut in a rectangular shape to be in contact with the end surfaces;
an insulating layer laminated on the transparent conductive film; and
a metal layer laminated on the insulating layer.

2. The semiconductor laser element according to claim 1, wherein the nitride semiconductor layer of the first conductivity type includes a cladding layer and a guide layer.

3. The semiconductor laser element according to claim 1, wherein the nitride semiconductor layer of the second conductivity type includes a cladding layer and a guide layer.

4. The semiconductor laser element according to claim 1, wherein
the metal layer includes a pad metal layer, a barrier metal layer, and a bonding metal layer.

5. The semiconductor laser element according to claim 4, wherein the metal layer laminated on the cleavage line to be a front end surface and a rear end surface is a barrier metal layer.

6. The semiconductor laser element according to claim 1, wherein the transparent conductive film includes indium tin oxide (ITO), indium titanium oxide (ITiO), aluminum oxide-doped zinc oxide (AZO), or IGZO (InGaZnOx).

7. The semiconductor laser element according to claim 1, wherein a region of the transparent conductive film sandwiched between the transparent conductive film side bands and cut in a rectangular shape is covered with an insulating layer.

8. The semiconductor laser element according to claim 1, wherein the transparent conductive film formed in a pattern, a character, a symbol, or a combination thereof is disposed in the region of the transparent conductive film sandwiched between the transparent conductive film side bands and cut into the rectangular shape.

9. The semiconductor laser element according to claim 1, wherein the pattern, the character, the symbol, or the combination thereof of the transparent conductive film formed in the region of the transparent conductive film sandwiched between the transparent conductive film side bands and cut into the rectangular shape is different between a front end surface and a rear end surface.
